(19) United States
(12) Patent Application Publication
(10) Pub. No.: US 2026/0343774 A1
(43) Pub. Date: Oct. 29, 2026

(54) TRACTION INVERTER

(71) Applicant: DELTA ELECTRONICS, INC., Taoyuan City (TW)

(72) Inventors: Guan-Ying WANG, Shanghai (CN); Pei-Ai YOU, Shanghai (CN); Gong-Qun WANG, Shanghai (CN)

(21) Appl. No.: 19/651,798

(22) Filed: Apr. 20, 2026

(30) Foreign Application Priority Data
Apr. 27, 2025 (CN) 202510537418.4

(51) Int. Cl. H05K 7/14; H02M 7/00

(52) U.S. Cl. CPC H05K 7/1432; H02M 7/003

(57) ABSTRACT

A traction inverter includes a base plate, a printed circuit board, a plastic frame, a plurality of busbars and a plurality of sensors. The plastic frame includes a plurality of first supporting pillars. The plastic frame is at least partially located between the base plate and the printed circuit board. The first supporting pillars abut against the printed circuit board. The busbars are respectively and at least partially embedded inside the plastic frame. Each of the busbars is located between adjacent two of the first supporting pillars. The sensors are disposed on the printed circuit board and aligned with the busbars. Each of the sensors and a corresponding one of the busbars are spaced apart from each other by a distance. The distance is within a predetermined range.

### RELATED APPLICATIONS

This application claims priority to Chinese Application Serial Number 202510537418.4, filed Apr. 27, 2025, which is herein incorporated by reference in its entirety.

### BACKGROUND

### Technical Field

The present disclosure relates to traction inverters utilized in electric vehicles.

### Description of Related Art

In recent years, electric vehicles have become increasingly popular among consumers due to their significant advantages, such as high efficiency, energy savings, low noise and zero emissions.

In an electric vehicle, the traction inverter is a critical component, which is responsible for efficiently converting and regulating electrical energy to achieve vehicle propulsion and energy management. Specifically, the traction inverter is primarily used to convert direct current (DC) into alternating current (AC) to drive a motor, thereby enabling vehicle movement. Additionally, the traction inverter can adjust the speed and torque of the motor, allowing precise power control and adjustments based on the required acceleration or deceleration of the vehicle.

Since the traction inverter has a significant and direct impact on the performance of an electric vehicle, the way to optimize its efficiency at a low cost is undoubtedly an important issue that the industry highly concerns about.

### SUMMARY

According to an embodiment of the present disclosure, a traction inverter includes a base plate, a printed circuit board, a plastic frame, a plurality of busbars and a plurality of sensors. The plastic frame includes a plurality of first supporting pillars. The plastic frame is at least partially located between the base plate and the printed circuit board. The first supporting pillars abut against the printed circuit board. The busbars are respectively and at least partially embedded inside the plastic frame. Each of the busbars is located between adjacent two of the first supporting pillars. The sensors are disposed on the printed circuit board and aligned with the busbars. Each of the sensors and a corresponding one of the busbars are spaced apart from each other by a distance. The distance is within a predetermined range.

According to another embodiment of the present disclosure, a traction inverter includes a base plate, a printed circuit board, a plastic frame, at least one busbar and at least one sensor. The plastic frame is at least partially located between the base plate and the printed circuit board. The busbar is at least partially embedded inside the plastic frame. The sensor is disposed on the printed circuit board and aligned with the busbar. The printed circuit board is located between the sensor and the busbar. The sensor and the busbar are spaced apart from each other by a distance. The distance is within a predetermined range.

According to a further embodiment of the present disclosure, a traction inverter includes a base plate, a printed circuit board, a plastic frame, at least one busbar and at least one sensor. The plastic frame is at least partially located between the base plate and the printed circuit board. The busbar is at least partially embedded inside the plastic frame. The sensor is disposed on the printed circuit board and aligned with the busbar. The sensor is located between the printed circuit board and the busbar. The sensor and the busbar are spaced apart from each other by a distance. The distance is within a predetermined range.

### BRIEF DESCRIPTION OF THE DRAWINGS

The disclosure can be more fully understood by reading the following detailed description of the embodiments, with reference made to the accompanying drawings as follows:

FIG. 1 is a schematic view of a traction inverter according to an embodiment of the present disclosure;

FIG. 2 is a schematic view of a portion of the traction inverter of FIG. 1, in which the printed circuit board is omitted;

FIG. 3 is a sectional view along the sectional line A-A of FIG. 1;

FIG. 4 is a sectional view along the sectional line B-B of FIG. 3;

FIG. 5 is a sectional view along the sectional line C-C of FIG. 1; and

FIG. 6 is a sectional view of a portion of a traction inverter according to another embodiment of the present disclosure.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

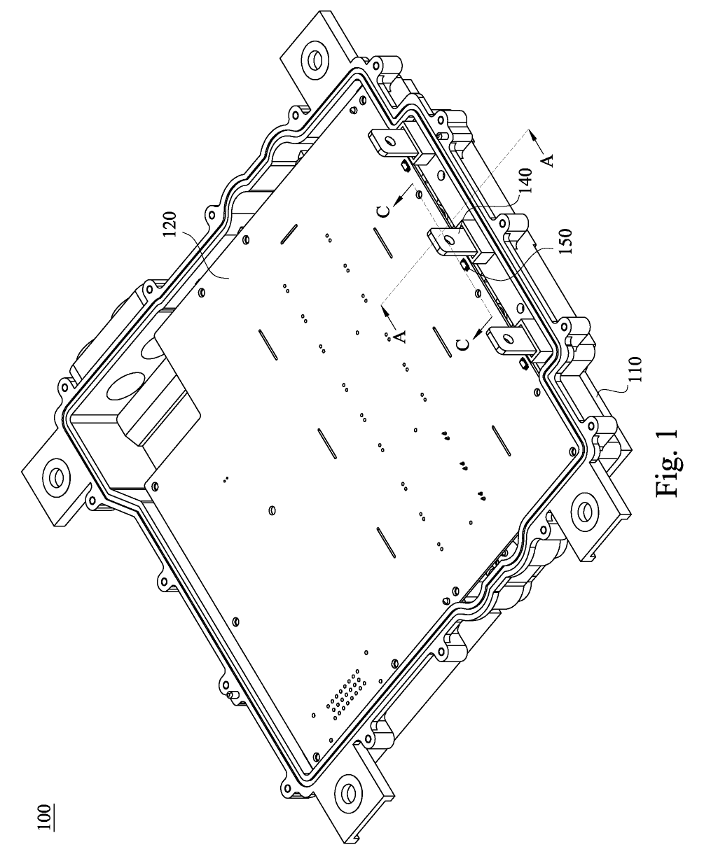

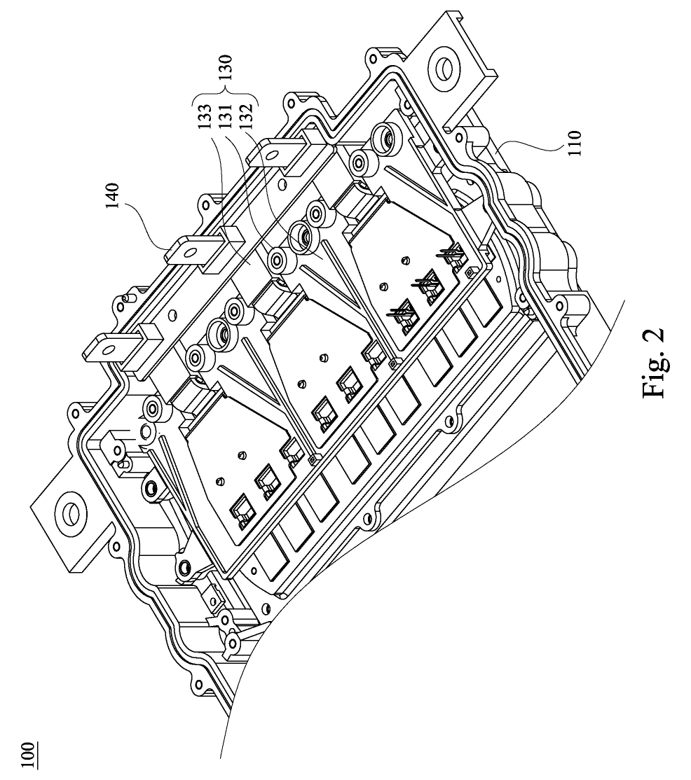

Reference is made to FIGS. 1-2. FIG. 1 is a schematic view of a traction inverter 100 according to an embodiment of the present disclosure. FIG. 2 is a schematic view of a portion of the traction inverter 100 of FIG. 1, in which the printed circuit board 120 is omitted. The present disclosure provides a traction inverter 100, which is suitable to be used in an electric vehicle, and is electrically connected between a motor and a DC power supply. In this embodiment, as shown in FIGS. 1-2, the traction inverter 100 includes a base plate 110, a printed circuit board 120, a plastic frame 130, a plurality of busbars 140 and a plurality of sensors 150. The busbars 140 are respectively and at least partially embedded inside the plastic frame 130. The plastic frame 130 is at least partially located between the base plate 110 and the printed circuit board 120. The sensors 150 are disposed on the printed circuit board 120 and aligned with the busbars 140. Each of the sensors 150 is configured to monitor data such as current and voltage of electricity flowing through a corresponding one of the busbars 140.

Furthermore, as shown in FIG. 2, the plastic frame 130 includes a first plate 132, a plurality of first supporting pillars 131 and a plurality of embedding portions 133. The first supporting pillars 131 and the embedding portions 133 are disposed on the first plate 132. Each of the embedding portions 133 is located between adjacent two of the first supporting pillars 131. Each of the busbars 140 is at least partially embedded in a corresponding one of the embedding portions 133. This means one of the embedding portions 133 matches with one of the busbars 140. Moreover, each of the embedding portions 133 is away from two opposite ends of a corresponding one of the busbars 140. This means two opposite ends of each of the busbars 140 are exposed out of a corresponding one of the embedding portions 133, such that the two opposite ends can be respectively connected with a power module (not shown) and a motor (not shown).

In practical applications, the plastic frame 130 is of an integrally formed structure. This means the first plate 132, the first supporting pillars 131 and the embedding portions 133 are made from a single piece of material, which facilitates to reducing the production cost of the plastic frame 130. Moreover, the integrally formed plastic frame 130 can reduce deviations caused by assembly, while also shortening the operating time required by production operators, thereby lowering the labor cost associated with assembly.

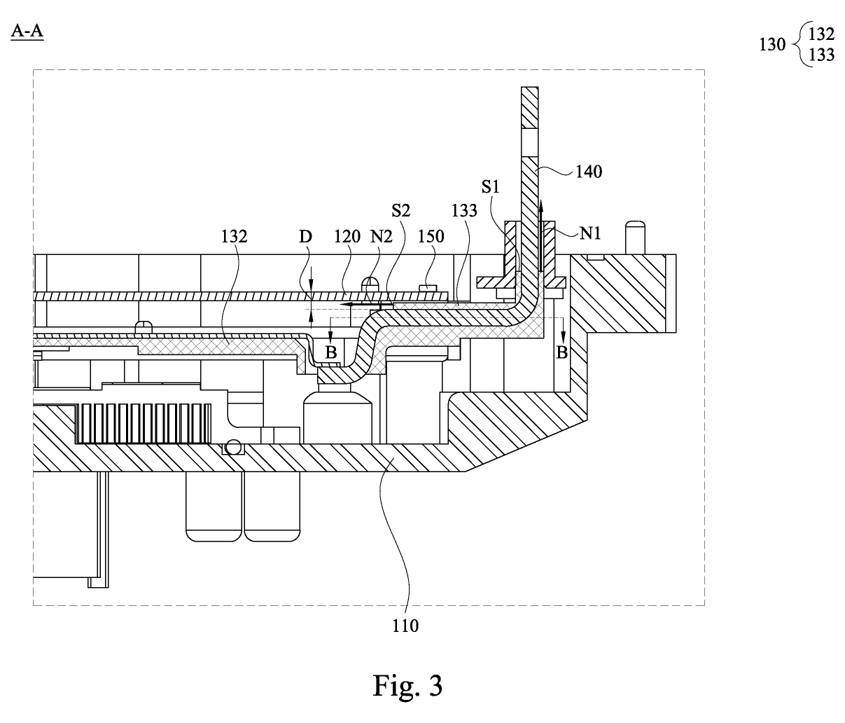

Reference is made to FIG. 3. FIG. 3 is a sectional view along the sectional line A-A of FIG. 1. In this embodiment, as shown in FIG. 3, the embedding portion 133 of the plastic frame 130 is at least partially located between the printed circuit board 120 and the busbar 140, while the embedding portion 133 is spaced apart from the printed circuit board 120. This means the embedding portion 133 and the printed circuit board 120 do not directly contact with each other. In this way, the heat generated by an electric current flowing through the busbar 140 will not be conducted to the printed circuit board 120.

It is worth noting that, as shown in FIG. 3, the sensor 150 is located at a side of the printed circuit board 120 away from the busbar 140. This means the printed circuit board 120 is located between the sensor 150 and the busbar 140. To be more specific, the sensor 150 and the busbar 140 are spaced apart from each other by a distance D, while the distance D is within a predetermined range. In this embodiment, the predetermined range of the distance D is between 2.74 mm and 4.74 mm. It is understood that this predetermined range can be set based on actual working conditions and does not intend to limit the present disclosure.

By maintaining the distance D between the sensor 150 and the busbar 140 to be within the range of 2.74 mm to 4.74 mm, the sensor 150 can monitor data such as current and voltage of electricity flowing through the busbar 140 in an accurate and effective manner.

Furthermore, in practical applications, the distance D has an allowable tolerance, and a range of the allowable tolerance is +/-0.1 mm. By maintaining the accuracy of the distance D between the sensor 150 and the busbar 140, the accuracy of monitoring by the sensor 150 can be further improved.

In other words, by precisely maintaining the distance D between the sensor 150 and the busbar 140, the sensor 150 can accurately and effectively monitor data such as current and voltage flowing through the busbar 140. Unlike the traditional use of magnetic rings, the traction inverter 100 can effectively reduce production costs.

On the other hand, as shown in FIG. 3, the embedding portion 133 has a first surface S1 and a second surface S2 opposite to the first surface S1. The first surface S1 has a first normal N1. The second surface S2 has a second normal N2. The first normal N1 and the second normal N2 intersect with each other. The busbar 140 penetrates through the first surface S1 and the second surface S2 of the embedding portion 133. In practice, the first normal N1 and the second normal N2 are perpendicular to each other. In other words, a portion of the busbar 140 penetrating out of the first surface S1 and another portion penetrating out of the second surface S2 are substantially perpendicular to each other.

To be more specific, the first surface S1 of each of the embedding portions 133 is exposed out of the printed circuit board 120. A portion of each of the busbars 140 penetrating out of a corresponding one of the first surfaces S1 is configured to be electrically connected with a motor. On the contrary, the second surface S2 of each of the embedding portions 133 is located between the printed circuit board 120 and the base plate 110. A portion of each of the busbars 140 penetrating out of a corresponding one of the second surfaces S2 is configured to be electrically connected with a power module.

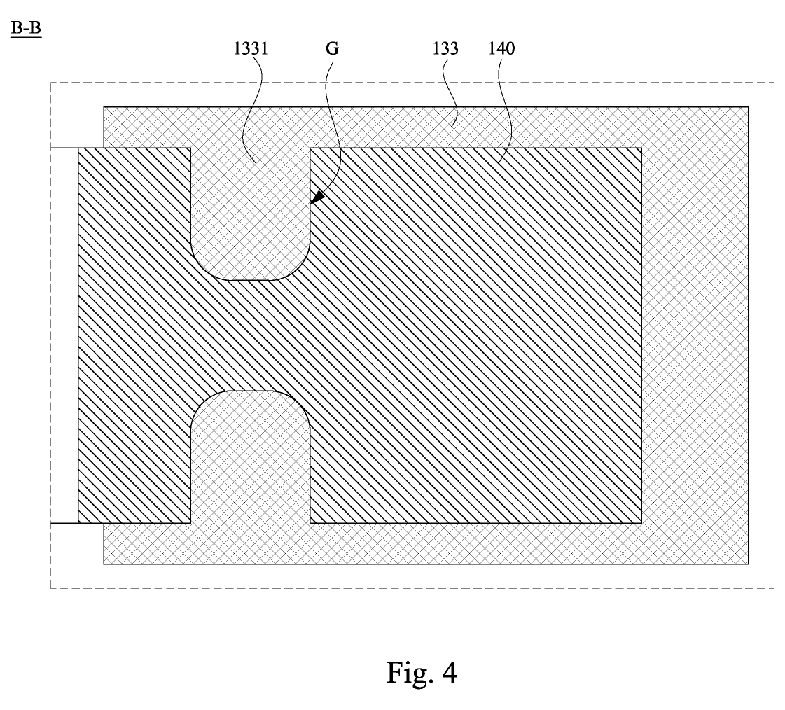

Reference is made to FIG. 4. FIG. 4 is a sectional view along the sectional line B-B of FIG. 3. In this embodiment, as shown in FIG. 4, the busbar 140 has two grooves G located at its opposite surfaces. Correspondingly, the embedding portion 133 has two protruding structures 1331 located at its inner surface. The protruding structures 1331 are at least partially located within the grooves G, so as to secure the position of the busbar 140 relative to the embedding portion 133. It is worth noting that, under such a situation, the busbar 140 can maintain its structural integrity. This means the busbar 140 is not assembled from multiple separate components. This not only maintains the integrity of the conductive surface of the busbar 140, but also enhances the structural strength of the busbar 140 and avoids deviations that would otherwise arise from assembling multiple components. Furthermore, the interface of the busbar 140 corresponding to the groove G is effectively reduced. This allows the formation of a stable magnetic field with the sensor 150, enabling the busbar 140 to transmit more precise current information to the sensor 150 within a stable magnetic field, which is then fed back to the motor.

On the other hand, since the plastic frame 130 is of an integrally formed structure, and each of the busbars 140 at least partially embedded inside (a corresponding one of the embedding portions 133 of) the plastic frame 130 has structural integrity, the traction inverter 100 requires fewer components. This makes the traction inverter 100 easier to assemble and enables effective space saving.

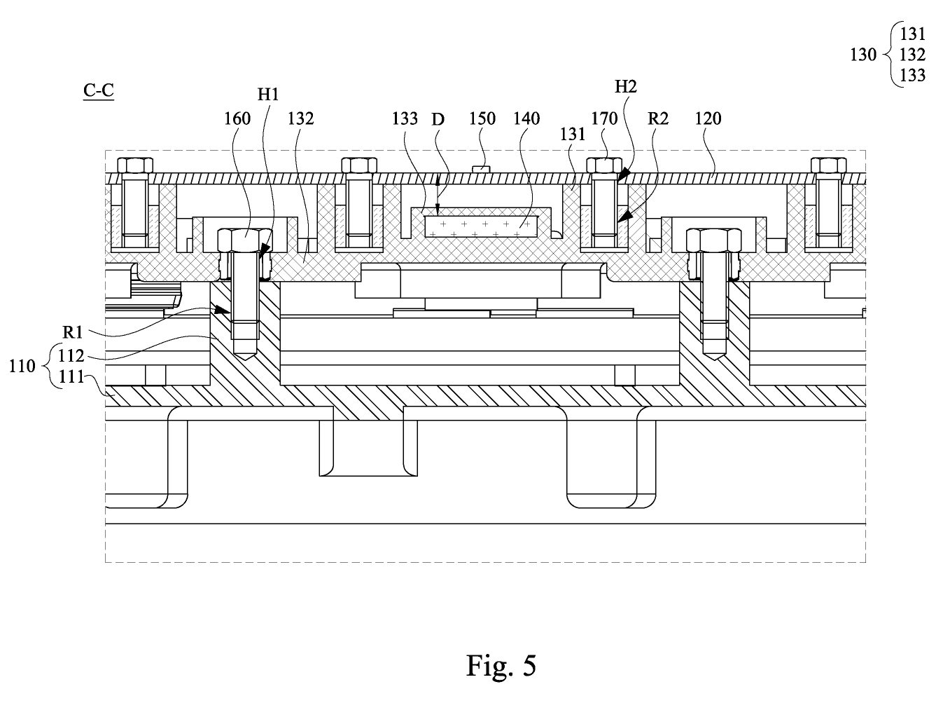

Reference is made to FIG. 5. FIG. 5 is a sectional view along the sectional line C-C of FIG. 1. In this embodiment, as shown in FIG. 5, the first supporting pillars 131 of the plastic frame 130 abut against the printed circuit board 120. Each of the embedding portions 133 and a corresponding one of the busbars 140 are located between adjacent two of the first supporting pillars 131.

Moreover, as shown in FIG. 5, the printed circuit board 120 has a plurality of second through holes H2. Each of the first supporting pillars 131 of the plastic frame 130 has a second screw hole R2. The second screw hole R2 of each of the first supporting pillars 131 is aligned with a corresponding one of the second through holes H2 of the printed circuit board 120. The traction inverter 100 further includes a plurality of second screws 170. The second screws 170 respectively penetrate through one of the second through holes H2 of the printed circuit board 120 and are respectively coupled with the second screw hole R2 of a corresponding one of the first supporting pillars 131. Since the second screws 170 fasten the printed circuit board 120 to the first supporting pillars 131 of the plastic frame 130, while the first supporting pillars 131 abut against the printed circuit board 120 and are respectively positioned close to a corresponding one of the embedding portions 133, the distance between the printed circuit board 120 and the embedding portions 133 can be stably maintained, thereby further maintaining the distance D between each of the sensors 150 and a corresponding one of the busbars 140.

In addition, as shown in FIG. 5, the first plate 132 of the plastic frame 130 further has a plurality of first through holes H1. Each of the embedding portions 133 is located between adjacent two of the first through holes H1. Each of the first supporting pillars 131 is located between a corresponding one of the embedding portions 133 and a corresponding one of the first through holes H1.

Moreover, as shown in FIG. 5, the base plate 110 includes a second plate 111 and a plurality of second supporting pillars 112. The second supporting pillars 112 are connected with the second plate 111 and abut against the first plate 132 of the plastic frame 130. Each of the second supporting pillars 112 has a first screw hole R1. Correspondingly, the first screw hole R1 of each of the second supporting pillars 112 is aligned with a corresponding one of the first through holes H1 of the plastic frame 130. The traction inverter 100 further includes a plurality of first screws 160. The first screws 160 respectively penetrate through one of the first through holes H1 of the plastic frame 130 and are respectively coupled with the first screw hole R1 of a corresponding one of the second supporting pillars 112, such that the plastic frame 130 is fastened to the second supporting pillars 112 of the base plate 110.

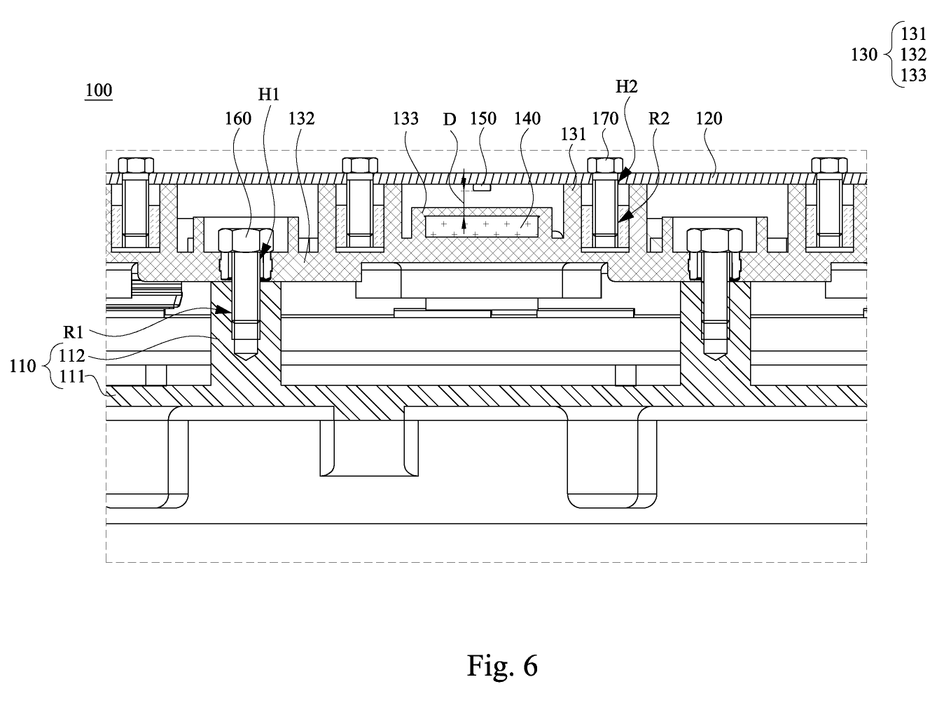

Reference is made to FIG. 6. FIG. 6 is a sectional view of a portion of a traction inverter 100 according to another embodiment of the present disclosure. In this embodiment, as shown in FIG. 6, the sensor 150 is located at a side of the printed circuit board 120 close to the busbar 140, according to the actual situation. This means the sensor 150 is located between the printed circuit board 120 and the busbar 140. Under such a situation, similarly, the sensor 150 and the busbar 140 are spaced apart from each other by a distance D, in which the distance D is within a predetermined range, and the predetermined range of the distance D is also between 2.74 mm and 4.74 mm. Moreover, in practical applications, after being fixed, the distance D has an allowable tolerance, and a range of the allowable tolerance is also +/-0.1 mm.

In conclusion, the aforementioned embodiments of the present disclosure have at least the following advantages:
(1) Since the plastic frame is of an integrally formed structure, and each of the busbars at least partially embedded inside (a corresponding one of the embedding portions of) the plastic frame has structural integrity, the traction inverter requires fewer components. This makes the traction inverter easier to assemble and enables effective space saving.
(2) Since the second screws fasten the printed circuit board to the first supporting pillars of the plastic frame, while the first supporting pillars abut against the printed circuit board and are respectively positioned close to a corresponding one of the embedding portions, the distance between the printed circuit board and the embedding portions can be stably maintained, thereby further maintaining the distance between each of the sensors and a corresponding one of the busbars.
(3) By precisely maintaining the distance between the sensor and the busbar, the sensor can accurately and effectively monitor data such as current and voltage flowing through the busbar. Unlike the traditional use of magnetic rings, the traction inverter can effectively reduce production costs.
(4) Since the structural integrity of the busbar is maintained, this not only maintains the integrity of the conductive surface of the busbar, but also enhances the structural strength of the busbar and avoids deviations that would otherwise arise from assembling multiple components. Furthermore, the interface of the busbar corresponding to the groove is effectively reduced. This allows the formation of a stable magnetic field with the sensor, enabling the busbar to transmit more precise current information to the sensor within a stable magnetic field, which is then fed back to the motor. In addition, since the embedding portion of the plastic frame is at least partially located between the printed circuit board and the busbar, while the embedding portion is spaced apart from the printed circuit board, the heat generated by an electric current flowing through the busbar will not be conducted to the printed circuit board.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A traction inverter, comprising:
a base plate;
a printed circuit board;
a plastic frame comprising a plurality of first supporting pillars, the plastic frame being at least partially located between the base plate and the printed circuit board, the first supporting pillars abutting against the printed circuit board;
a plurality of busbars respectively and at least partially embedded inside the plastic frame, each of the busbars being located between adjacent two of the first supporting pillars; and
a plurality of sensors disposed on the printed circuit board and aligned with the busbars, each of the sensors and a corresponding one of the busbars being spaced apart from each other by a distance, the distance being within a predetermined range.

2. The traction inverter of claim 1, wherein the plastic frame further comprises:
a first plate, the first supporting pillars are disposed on the first plate; and
a plurality of embedding portions disposed on the first plate, each of the embedding portions is located between adjacent two of the first supporting pillars, each of the busbars is at least partially embedded in a corresponding one of the embedding portions, each of the embedding portions is away from two opposite ends of a corresponding one of the busbars.

3. The traction inverter of claim 2, wherein the embedding portions are respectively spaced apart from the printed circuit board.

4. The traction inverter of claim 2, wherein each of the embedding portions has a first surface and a second surface opposite to the first surface, the first surface has a first normal, the second surface has a second normal, the first normal and the second normal intersect with each other, each of the busbars penetrates through the first surface and the second surface of a corresponding one of the embedding portions.

5. The traction inverter of claim 4, wherein the first surfaces are exposed out of the printed circuit board, a portion of each of the busbars penetrating out of a corresponding one of the first surfaces is configured to be electrically connected with a motor, the second surfaces are located between the printed circuit board and the base plate, a portion of each of the busbars penetrating out of a corresponding one of the second surfaces is configured to be electrically connected with a power module.

6. The traction inverter of claim 2, wherein the first plate has a plurality of first through holes, each of the embedding portions is located between adjacent two of the first through holes, each of the first supporting pillars is located between a corresponding one of the embedding portions and a corresponding one of the first through holes,
the base plate comprises:
a second plate; and
a plurality of second supporting pillars connected with the second plate and abutting against the first plate, each of the second supporting pillars has a first screw hole aligned with a corresponding one of the first through holes,
the traction inverter further comprises:
a plurality of first screws respectively penetrating through one of the first through holes and coupled with a corresponding one of the first screw holes.

7. The traction inverter of claim 2, wherein the first plate, the first supporting pillars and the embedding portions are integrally formed.

8. The traction inverter of claim 2, wherein at least one of the busbars has a plurality of grooves opposite to each other, at least one of the embedding portions has a plurality of protruding structures disposed at an inner surface of said one of the embedding portions, the protruding structures are at least partially located within the grooves.

9. The traction inverter of claim 1, wherein the printed circuit board has a plurality of second through holes, each of the first supporting pillars has a second screw hole aligned with a corresponding one of the second through holes,
the traction inverter further comprises:
a plurality of second screws respectively penetrating through one of the second through holes and coupled with a corresponding one of the second screw holes.

10. The traction inverter of claim 1, wherein at least one of the sensors is located at a side of the printed circuit board away from the busbars.

11. The traction inverter of claim 1, wherein at least one of the sensors is located at a side of the printed circuit board close to the busbars.

12. The traction inverter of claim 1, wherein the distance has an allowable tolerance, a range of the allowable tolerance is +/-0.1 mm.

13. The traction inverter of claim 1, wherein the predetermined range is between 2.74 mm and 4.74 mm.

14. A traction inverter, comprising:
a base plate;
a printed circuit board;
a plastic frame at least partially located between the base plate and the printed circuit board;
at least one busbar at least partially embedded inside the plastic frame; and
at least one sensor disposed on the printed circuit board and aligned with the busbar, the printed circuit board being located between the sensor and the busbar, the sensor and the busbar being spaced apart from each other by a distance, the distance being within a predetermined range.

15. The traction inverter of claim 14, wherein the predetermined range is between 2.74 mm and 4.74 mm.

16. A traction inverter, comprising:
a base plate;
a printed circuit board;
a plastic frame at least partially located between the base plate and the printed circuit board;
at least one busbar at least partially embedded inside the plastic frame; and
at least one sensor disposed on the printed circuit board and aligned with the busbar, the sensor being located between the printed circuit board and the busbar, the sensor and the busbar being spaced apart from each other by a distance, the distance being within a predetermined range.

17. The traction inverter of claim 16, wherein the plastic frame comprises:
a plate;
a plurality of supporting pillars disposed on the plate and abutting against the printed circuit board; and
at least one embedding portion disposed on the plate and located between adjacent two of the supporting pillars, the busbar is at least partially embedded in the embedding portion, the embedding portion exposes two opposite ends of the busbar, the embedding portion is spaced apart from the sensor.

18. The traction inverter of claim 16, wherein the predetermined range is between 2.74 mm and 4.74 mm.
